(19) United States
(12) Patent Application Publication
(10) Pub. No.: US 2008/0160672 A1
(43) Pub. Date: Jul. 3, 2008

(54) METHOD FOR MANUFACTURING SEMICONDUCTOR DEVICE

(76) Inventor: Ji-Ho Hong, Gyeongi-do (KR)

Correspondence Address: SHERR & NOURSE, PLLC, 620 HERNDON PARKWAY, SUITE 200, HERNDON, VA, 20170, US

(21) Appl. No.: 11/957,233

(22) Filed: Dec. 14, 2007

(30) Foreign Application Priority Data
Dec. 27, 2006 (KR) 10-2006-0135755

(51) Int. Cl. H01L 21/00

(52) U.S. Cl. 438/107; 257/E21.001

(57) ABSTRACT

A method for manufacturing a semiconductor device including a cell area and a peripheral area. The peripheral area includes a low voltage area and a high voltage area. The cell area can be manufactured as a chip in a first wafer, the low voltage area can be manufactured as a chip in a second wafer and the high voltage area can be manufactured as a chip in a third wafer. A sawing process can then be performed to cut respective chips formed in the first through third wafers. First through third packaging areas can then be formed in a fourth wafer as spaces for packaging the chips.

The present application claims priority under 35 U.S.C. 119 and 35 U.S.C. 365 to Korean Patent Application No. 10-2006-0135755 (filed on Dec. 27, 2006), which is hereby incorporated by reference in its entirety.

### BACKGROUND

A flash memory device is a semiconductor device that may include a cell area and a peripheral area. The peripheral area may be divided into a high voltage area where a high voltage transistor may be formed, and a low voltage area where a low voltage transistor may be formed. The cell area is an area where the characteristics of the flash memory device may be most effectively realized. The cell area may provide a clear difference in an aspect of an overall process depending on the purpose and shape of the particular semiconductor device.

The cell area may require a high integration of semiconductor devices. A more precise design rule may be applied to the cell area rather than other area s within the semiconductor device according to a request for such high integration. Accordingly, new technologies under development may be actively applied to the cell area.

On the other hand, the peripheral area of a flash memory device is an area to which an operating voltage of a device may be applied. The peripheral area less requires new technologies compared to the cell area in an aspect of integration or technology, that is, a design rule required by the cell area.

For example, in case of a cell area used for a 90 nm NOR flash process, the operation of an integrated cell may be realized with an operating voltage upon read/programming operation used for a related art 0.13 μm NOR flash process not changed much. Therefore, technology intended for the 90 nm technology may be indispensably required.

Also, since the degree of integration may indispensably increase in the 90 nm process, new technologies for integrating devices (e.g., an ArF lithographic process may be required also in an aspect of patterning) may be immediately applied to the cell area.

However, when a transistor in the peripheral area of a flash memory device is manufactured, the operation of the cell area of a 90 nm flash memory device may be secured even when a peripheral area manufactured according to a 0.13 μm device technology is applied for manufacturing the 90 nm flash memory device.

Therefore, since a cell area and a peripheral area may be realized while the same process is performed within the same wafer in manufacturing a flash memory device, highly integrated technology may be unnecessarily applied even to the peripheral area in order to form highly integrated cell area in an aspect of manufacturing costs of the peripheral area.

Moreover, for a flash memory device, the peripheral area may be divided into a first area including a plurality of low voltage logic transistors and second area including a plurality of high voltage logic transistors. In the high voltage transistor, the thicknesses of sidewall spacers may be sufficiently secured to prevent a punch phenomenon of a channel area during high voltage operation. However, in the case where an additional mask is not used, the thicknesses of the sidewall spacers with respect to a high voltage transistor in a peripheral area may be reduced as the integration degree of a cell increases. In this case, the probability of punch phenomenon generation may be further increased.

### SUMMARY

Embodiments relate to a method for manufacturing a semiconductor device such as a flash memory device that can reduce overall manufacturing costs by forming a plurality of area s using a separate wafer.

Embodiments relate to a method for manufacturing a semiconductor device that can include at least one of the following steps: manufacturing a cell area as a chip in a first wafer; manufacturing a low voltage area as a chip in a second wafer; manufacturing a high voltage area as a chip in a third wafer; performing a sawing process for cutting the respective chips formed in the first wafer, the second wafer and the third wafer; forming a fourth wafer having a first packaging area, a second packaging area and a third packaging area; and then packaging the first wafer in the first packaging area, the second wafer in the second packaging area, and the third wafer in the third packaging area.

Embodiments relate to a method for manufacturing a semiconductor device that can include at least one of the following steps: manufacturing a cell area as a chip in a first wafer, a low voltage area as a chip in a second wafer and a high voltage area as a chip in a third wafer; forming a fourth wafer having a first packaging area sized to receive the first wafer, a second packaging area sized to receive the second wafer, a first partition wall between the first packaging area and the second packaging area, a third packaging area sized to receive the third wafer, and a second partition wall between the second packaging area and the third packaging area; and then packaging the first wafer in the first packaging area, the second wafer in the second packaging area, and the third wafer in the third packaging area.

Embodiments relate to a method for manufacturing a semiconductor device that can include at least one of the following steps: manufacturing a cell area as a chip in a first wafer; manufacturing a low voltage area as a chip in a second wafer; manufacturing a high voltage area as a chip in a third wafer; cutting the respective chips formed in the first wafer, the second wafer and the third wafer; forming a fourth wafer having a first packaging area sized to receive the first wafer, a second packaging area sized to receive the second wafer and a third packaging area sized to receive the third wafer; packaging the first wafer in the first packaging area, the second wafer in the second packaging area, and the third wafer in the third packaging area; depositing a metal layer over the fourth wafer; and then patterning the metal layer.

### DRAWINGS

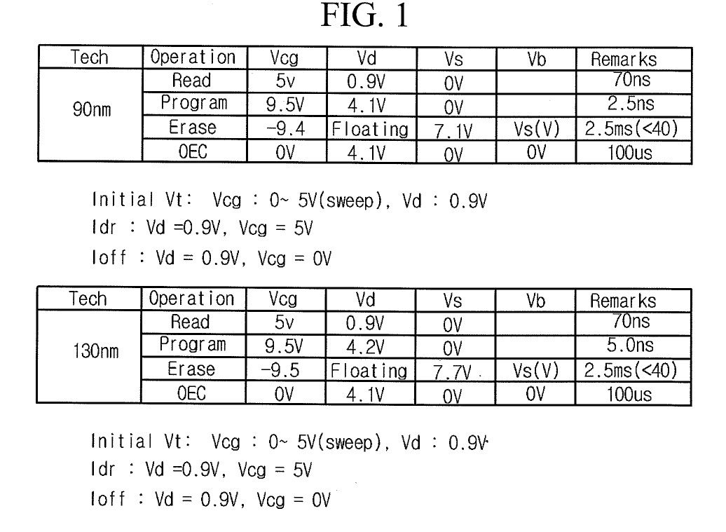

Example FIG. 1 illustrates an operating condition for a cell area of a NOR flash memory device.

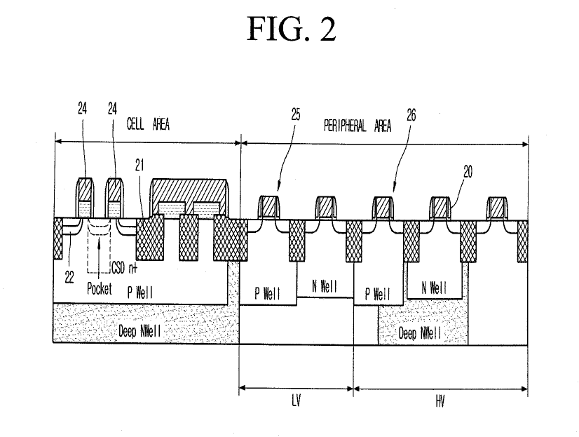

Example FIG. 2 illustrates a NOR flash memory device.

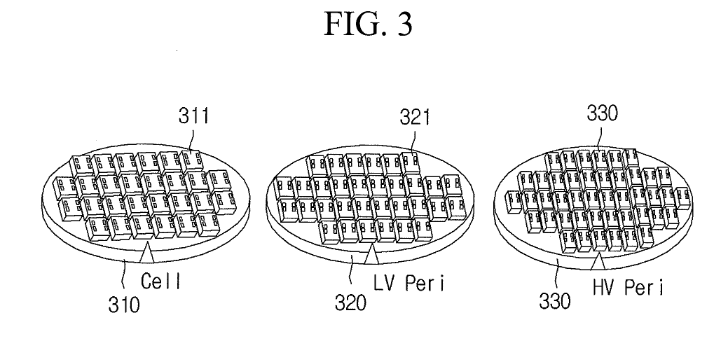

Example FIGS. 3 to 5 illustrate a method for manufacturing a semiconductor device, in accordance with embodiments.

### DESCRIPTION

As illustrated in example FIG. 1, read/program/erase operation conditions of a 90 nm NOR flash memory device and a 130 nm NOR flash memory device as a NOR flash memory device.

Read/program/erase operation conditions do not change much regardless of the 90 nm device and the 130 nm device. The operating characteristics of a cell area of a highly integrated 90 nm NOR flash memory device can be satisfied under circumstances of these similar operations conditions.

As illustrated in example FIG. 2, a NOR flash memory device can include a cell area and a peripheral area having a low voltage area and a high voltage area. Particularly, the cell area can include integration of devices as a memory capacity increases.

Device isolation layers 21 can be formed in a semiconductor substrate. P-type impurities can then be implanted to form P well, and lightly doped drain (LDD) areas 22 for forming source/drain area can then be formed. A gate stack including floating gate 23 and a control gate 24 can be formed on and/or over the semiconductor substrate. A pair of spacers can then be formed on and/or over the lateral sides of the gate stack.

Also, the peripheral area can include a high voltage area and a low voltage area. P-type impurities can be implanted into the substrate to form a P-well, and N-type impurities can be implanted into the substrate to form an N-well. A transistor can then be formed in the P-well and the N-well.

Particularly, spacers 20 can be formed on both lateral sides of a high voltage (HV) transistor, respectively, and can have a greater thickness than those spacers formed of a low voltage (LV) transistor. This is a result formed by performing an additional photolithographic process in order to prevent a punch phenomenon in a channel area of the high voltage transistor. Forming spacers 20 on the high voltage transistor having a greater thickness than the spacers on the low voltage transistor can be done by using an additional mask process, which can increase manufacturing costs.

A manufacturing method in accordance with embodiments can serve to reduce such manufacturing costs by separately manufacturing chips of an integrated cell area and chips of a high voltage area, and packaging these chips.

As illustrated in example FIG. 3, a flash memory device having the structure illustrated in example FIG. 2 can have a cell area, a low voltage area and a high voltage area manufactured on and/or over separate wafers. Particularly, cell area chip 311 can be manufactured in first wafer 310, low voltage chip 321 of the low voltage area provided in the peripheral area can be manufactured in second wafer 320, and high voltage chip 331 provided in the peripheral area can be manufactured in third wafer 330.

Accordingly, in accordance with embodiments, the cell area and the peripheral area are not simultaneously formed in a single wafer, but a plurality of wafers are provided and respective areas forming the flash memory device can be separately manufactured in the respective wafers. Therefore, each of first wafer 310, second wafer 320 and third wafer 330 can be processed in separate processes.

Particularly, only a process for forming the cell area of the flash memory device can be performed using first wafer 310. Only a process for forming the low voltage area in the peripheral area of the flash memory device can be performed using second wafer 320, and only a process for forming the high voltage area in the peripheral area of the flash memory device can be performed using the third wafer 330.

Accordingly, to form a highly integrated cell area, high integration technology does not need to be applied up to the peripheral area that does not require high integration technology. For example, a 90 nm flash memory device process can be applied using first wafer 310 to manufacture highly integrated cell area chip 311. A 130 nm flash memory device technology can be applied using second wafer 320 to form the low voltage area of the peripheral area.

As illustrated in example, after manufacturing cell area chip 311, low voltage 321, and high voltage 331 using the plurality of wafers, a sawing process for cutting the respective chips can then be performed.

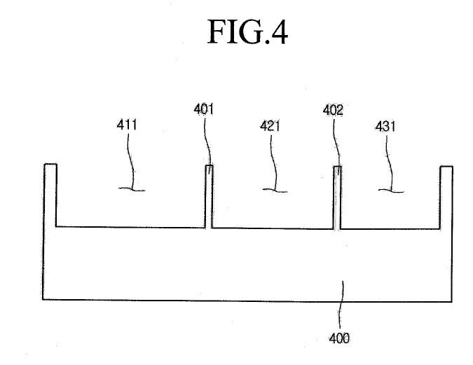

As illustrated in example FIG. 4, fourth wafer 400 may then be provided, and a photolithographic process can be performed to pattern fourth wafer 400. Next, an etching process for etching a portion of fourth wafer 400 can be performed. During the etching of fourth wafer 400, a sawing process for separating the respective chips formed in first wafer 310, second wafer 320 and third wafer 330 can be performed. A process for incorporating the respective chips into fourth chip 400 can then be performed.

During the etching of fourth wafer 400, first packaging area 411 can be formed as a space for packaging cell area chip 311 formed in first wafer 310. Second packaging area 421 can also be formed as a space for packaging low voltage chip 321 formed in second wafer 320. Third packaging area 431 can also be formed as a space for packaging high voltage chip 331 formed in third wafer 330. First packaging area 411, second packaging area 421 and third packaging area 431 can have a predetermined depth. Of course, cell area chip 311, low voltage 321, and high voltage 331 should be designed in advance with consideration of the sizes of packaging areas 411, 421, and 431.

As first packaging area 411, second packaging area 421 and third packaging area 431 are formed in fourth wafer 400, first partition wall 401 can be formed between first packaging area 411 and second packaging area 421. Second partition wall 402 can also be formed between second packaging area 421 and third packaging area 431.

After packaging cell area chip 311, low voltage 321, and high voltage 331 in fourth wafer 400, a flash memory device having the structure illustrated in example FIG. 2 is formed.

Next, a metal layer can then be deposited on and/or over fourth wafer 400 and then patterned to form a metal interlayer connection. After patterning the metal layer, a passivation layer can be formed on and/or over the metal interlayer to facilitate the performance of additional processes for packaging the flash memory device.

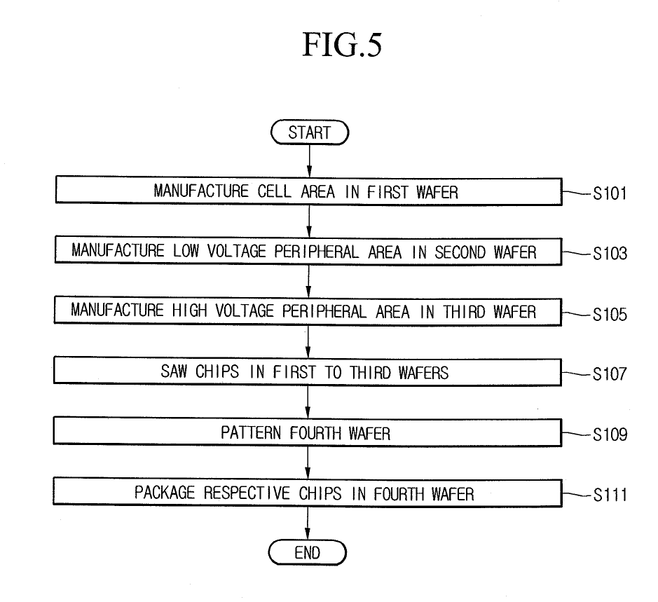

As illustrated in example FIG. 5, a method of manufacturing a flash memory device in accordance with embodiments can include step S101 of manufacturing cell areas as chips in a first wafer. In step S103, low voltage areas can be then be manufactured in a peripheral area of the flash memory device as chips in a second wafer. In step S105, high voltage areas may then be manufacturing in the peripheral area as chips in the third wafer. Since the processes for forming the respective chips in the first, second and third wafers can be performed simultaneously in other technology equipment, it can be noted that the processes are not illustrated according to a time sequenced order.

In step S107, a sawing process for cutting the chips formed in the first, second and third wafers can then be performed to separate the chips into individual chips. Only one of a cell area, a low voltage area and a high voltage area can be formed in each chip.

Next, in step S109 a fourth wafer can then be provided, and a photolithographic process and an etching process can be performed to package respective chips to form a first packaging area for forming cell area chip 311, a second packaging area for forming low voltage chip 321, and a third packaging area for forming high voltage chip 331 in the fourth wafer.

In step S111, cell area chip 311, low voltage chip 321 and high voltage chip 331 can then be packaged in the fourth wafer, and thus, the flash memory device is formed.

An additional step can include, after packaging cell area chip 311, low voltage 321, and high voltage 331 in fourth wafer 400, a metal layer for electrically connecting with the respective chips can then be deposited and patterned, and a passivation layer can then be deposited on and/or over the metal interlayer layer.

In accordance with embodiments, a cell area requiring high integration and a peripheral area not requiring high integration can be manufactured in separate wafers, respectively, and then packaged in order to reduce overall manufacturing costs.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
manufacturing a cell area as a chip in a first wafer;
manufacturing a low voltage area as a chip in a second wafer;
manufacturing a high voltage area as a chip in a third wafer;
performing a sawing process for cuffing the respective chips formed in the first wafer, the second wafer and the third wafer;
forming a fourth wafer having a first packaging area, a second packaging area and a third packaging area; and then
packaging the first wafer in the first packaging area, the second wafer in the second packaging area, and the third wafer in the third packaging area.

2. The method of claim 1, wherein forming the fourth wafer comprises performing a photolithographic process and an etching process on the fourth wafer to etch the fourth wafer to a predetermined depth.

3. The method of claim 1, wherein forming the fourth wafer comprises forming a first partition wall between the first packaging area and the second packaging area and forming a second partition wall between the second packaging area and the third packaging area.

4. The method of claim 1, further comprising, after packaging the first wafer in the first packaging area, the second wafer in the second packaging area, and the third wafer in the third packaging area:
depositing a metal layer over the fourth wafer; and then
patterning the metal layer.

5. The method of claim 1, wherein packaging the first wafer in the first packaging area, the second wafer in the second packaging area, and the third wafer in the third packaging area comprises:
packaging the chip in the cell area in the first packaging area;
packaging the chip in the low voltage area in the second packaging area; and
packaging the chip in the high voltage area in the third packaging area.

6. The method of claim 1, wherein the sizes of the chips in the respective cell area, the low voltage area, and the high voltage area are designed in advance with consideration of sizes of the respective packaging areas.

7. The method of claim 1, wherein the first packaging area, the second packaging area and the third packaging area each have a predetermined depth.

8. A method comprising:
manufacturing a cell area as a chip in a first wafer, a low voltage area as a chip in a second wafer and a high voltage area as a chip in a third wafer;
forming a fourth wafer having a first packaging area sized to receive the first wafer, a second packaging area sized to receive the second wafer, a first partition wall between the first packaging area and the second packaging area, a third packaging area sized to receive the third wafer, and a second partition wall between the second packaging area and the third packaging area; and then
packaging the first wafer in the first packaging area, the second wafer in the second packaging area, and the third wafer in the third packaging area.

9. The method of claim 8, wherein forming the fourth wafer comprises performing a photolithographic process and an etching process on the fourth wafer.

10. The method of claim 8, further comprising, after packaging the first wafer in the first packaging area, the second wafer in the second packaging area, and the third wafer in the third packaging area:
depositing a metal layer over the fourth wafer; and then
patterning the metal layer.

11. The method of claim 1, wherein the first packaging area the second packaging area and the third packaging area each have a predetermined depth.

12. A method comprising:
manufacturing a cell area as a chip in a first wafer;
manufacturing a low voltage area as a chip in a second wafer;
manufacturing a high voltage area as a chip in a third wafer;
cutting the respective chips formed in the first wafer, the second wafer and the third wafer;
forming a fourth wafer having a first packaging area sized to receive the first wafer, a second packaging area sized to receive the second wafer and a third packaging area sized to receive the third wafer;
packaging the first wafer in the first packaging area, the second wafer in the second packaging area, and the third wafer in the third packaging area;
depositing a metal layer over the fourth wafer; and then
patterning the metal layer.

13. The method of claim 12, wherein forming the fourth wafer comprises performing a photolithographic process and an etching process on the fourth wafer to etch the fourth wafer to a predetermined depth.

14. The method of claim 12, wherein the fourth wafer includes a first partition wall between the first packaging area and the second packaging area and a second partition wall between the second packaging area and the third packaging area.

15. The method of claim 12, further comprising, after packaging the first wafer in the first packaging area, the second wafer in the second packaging area, and the third wafer in the third packaging area:

16. The method of claim 12, wherein packaging the first wafer in the first packaging area, the second wafer in the second packaging area, and the third wafer in the third packaging area comprises:
packaging the chip in the cell area in the first packaging area;
packaging the chip in the low voltage area in the second packaging area; and
packaging the chip in the high voltage area in the third packaging area.

17. The method of claim 12, wherein the sizes of the chips in the respective cell area, the low voltage area, and the high voltage area are designed in advance with consideration of sizes of the respective packaging areas.

18. The method of claim 12, wherein the first packaging area, the second packaging area and the third packaging area each have a predetermined depth.
